(19) United States
(12) Patent Application Publication
(10) Pub. No.: US 2015/0179602 A1
(43) Pub. Date: Jun. 25, 2015

(54) INTEGRATED CIRCUIT PACKAGING SYSTEM WITH CONDUCTIVE INK AND METHOD OF MANUFACTURE THEREOF

(71) Applicants: Zigmund Ramirez Camacho, Singapore (SG); Bartholomew Liao, Singapore (SG); Sheila Marie L. Alvarez, Singapore (SG); Kelvin Dao, Singapore (SG)

(72) Inventors: Zigmund Ramirez Camacho, Singapore (SG); Bartholomew Liao, Singapore (SG); Sheila Marie L. Alvarez, Singapore (SG); Kelvin Dao, Singapore (SG)

(21) Appl. No.: 14/136,274

(22) Filed: Dec. 20, 2013

(51) Int. Cl. H01L 23/00

(52) U.S. Cl. CPC H01L 24/82; H01L 24/14; H01L 24/25; H01L 24/11

(57) ABSTRACT

An integrated circuit packaging system and method of manufacture thereof including: an integrated circuit die having a contact pad; a redistribution layer on the contact pad, the redistribution layer having a chip contact, a trace, and a bump pad, the redistribution layer having a curved top surface and sidewalls which are planar; an upper passivation layer on the sidewalls of the redistribution layer with the area above the bump pad of the redistribution layer exposed from the upper passivation layer; and an external interconnect attached over the bump pad.

### TECHNICAL FIELD

The present invention relates generally to an integrated circuit packaging system, and more particularly to a system with a redistribution layer.

### BACKGROUND ART

Semiconductor chips have become progressively more complex, driven in large part by the need for increasing processing power in a smaller chip size for compact or portable electronic devices such as cell phones, smart phones, personal media systems, or ultraportable computers.

A redistribution layer (RDL) can allow the use of smaller chip sizes while still having access to all contact points. The RDL can be formed in a “fan-in” or “fan-out” configuration, depending on the application. However, creating the RDL at small scales with the required precision can be a time-consuming and expensive process.

Thus, a need still remains for a precise and cost-effective way of creating an RDL. In view of the shrinking sizes of electronic components, it is increasingly critical that answers be found to these problems. In view of the ever-increasing commercial competitive pressures, along with growing consumer expectations and the diminishing opportunities for meaningful product differentiation in the marketplace, it is critical that answers be found for these problems. Additionally, the need to reduce costs, improve efficiencies and performance, and meet competitive pressures adds an even greater urgency to the critical necessity for finding answers to these problems.

Solutions to these problems have been long sought but prior developments have not taught or suggested any solutions and, thus, solutions to these problems have long eluded those skilled in the art.

### DISCLOSURE OF THE INVENTION

The present invention provides a method of manufacture of an integrated circuit packaging system including: providing an integrated circuit die having a contact pad; depositing a lower passivation layer on the integrated circuit die leaving the contact pad exposed; patterning a pattern mask having mask openings on the lower passivation layer; forming a redistribution layer on the contact pad and the lower passivation layer by depositing a conductive ink in the mask openings; removing the pattern mask; depositing an upper passivation layer over the redistribution layer leaving a portion of the redistribution layer exposed; and attaching an external interconnect to the redistribution layer.

The present invention provides an integrated circuit packaging system, including: an integrated circuit die having a contact pad; a redistribution layer on the contact pad, the redistribution layer having a chip contact, a trace, and a bump pad, the redistribution layer having a curved top surface and sidewalls which are planar; an upper passivation layer on the sidewalls of the redistribution layer with the area above the bump pad of the redistribution layer exposed from the upper passivation layer; and an external interconnect attached over the bump pad.

Certain embodiments of the invention have other steps or elements in addition to or in place of those mentioned above. The steps or element will become apparent to those skilled in the art from a reading of the following detailed description when taken with reference to the accompanying drawings.

### BRIEF DESCRIPTION OF THE DRAWINGS

FIG. 1 is a plan view of an integrated circuit packaging system in a first embodiment of the present invention.

FIG. 2 is a cross-sectional view of the integrated circuit packaging system along the section line 2-2 of FIG. 1.

FIG. 3 is a cross-sectional view of a wafer in a manufacturing step of the integrated circuit packaging system of FIG. 2.

FIG. 4 is the structure of FIG. 3 in a lower passivation phase of manufacture.

FIG. 5 is the structure of FIG. 4 in a pattern mask application phase of manufacture.

FIG. 6 is the structure of FIG. 5 in a printing phase of manufacture.

FIG. 7 is a cross-sectional view of the structure of FIG. 6 along the section line 7-7 of FIG. 6.

FIG. 8 is the structure of FIG. 6 in a pattern mask stripping phase of manufacture.

FIG. 9 is the structure of FIG. 7 in the pattern mask stripping phase of manufacture.

FIG. 10 is an exemplary isometric view of a portion of FIG. 8.

FIG. 11 is the structure of FIG. 8 in an upper passivation phase of manufacture.

FIG. 12 is the structure of FIG. 9 in the upper passivation phase of manufacture.

FIG. 13 is the structure of FIG. 11 in a solderability enhancement phase of manufacture.

FIG. 14 is a cross-sectional view of the integrated circuit packaging system as exemplified by the top view of FIG. 1 and along the section line 2-2 of FIG. 1 in a second embodiment of the present invention.

FIG. 15 is a cross-sectional view of the structure of FIG. 14 along the section line 15-15 of FIG. 14.

FIG. 16 is a structure similar to the structure of FIG. 5 in a printing phase of manufacture.

FIG. 17 is a cross-sectional view of the structure of FIG. 16 along the section line 17-17 of FIG. 16.

FIG. 18 is the structure of FIG. 16 in a plating phase of manufacture.

FIG. 19 is the structure of FIG. 17 in the plating phase of manufacture.

FIG. 20 is a top view of a portion of the structure of FIG. 18 in the plating phase of manufacture.

FIG. 21 is a flow chart of a method of manufacture of the integrated circuit packaging system in a further embodiment of the present invention.

FIG. 22 is a structure similar to the structure of FIG. 5 in an alternative printing phase of manufacture.

FIG. 23 is a cross-sectional view of the structure of FIG. 22 along the section line 23-23 of FIG. 22.

FIG. 24 is the structure of FIG. 22 in a pattern mask stripping phase of manufacture.

FIG. 25 is the structure of FIG. 23 in the pattern mask stripping phase of manufacture.

### BEST MODE FOR CARRYING OUT THE INVENTION

The following embodiments are described in sufficient detail to enable those skilled in the art to make and use the invention. It is to be understood that other embodiments would be evident based on the present disclosure, and that system, process, or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail.

The drawings showing embodiments of the system are semi-diagrammatic and not to scale and, particularly, some of the dimensions are for the clarity of presentation and are shown exaggerated in the drawing FIGs. Similarly, although the views in the drawings for ease of description generally show similar orientations, this depiction in the FIGs. is arbitrary for the most part. Generally, the invention can be operated in any orientation.

Where multiple embodiments are disclosed and described having some features in common, for clarity and ease of illustration, description, and comprehension thereof, similar and like features one to another will ordinarily be described with similar reference numerals. The embodiments have been numbered first embodiment, second embodiment, etc. as a matter of descriptive convenience and are not intended to have any other significance or provide limitations for the present invention.

For expository purposes, the term “horizontal” as used herein is defined as a plane parallel to the plane or surface of the active side of the integrated circuit die, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane, as shown in the figures. The term “on” means that there is direct contact between elements. The term “directly on” means that there is direct contact between one element and another element without an intervening element.

The term “active side” refers to a side of a die, a module, a package, or an electronic structure having active circuitry fabricated thereon or having elements for connection to the active circuitry within the die, the module, the package, or the electronic structure.

The term “processing” as used herein includes deposition of material or photoresist, patterning, exposure, development, etching, cleaning, and/or removal of the material or photoresist as required in forming a described structure.

Wavy lines are used throughout the figures to show that only a portion of the full structure is being shown. Portions of the structures and components are omitted for simplicity and clarity.

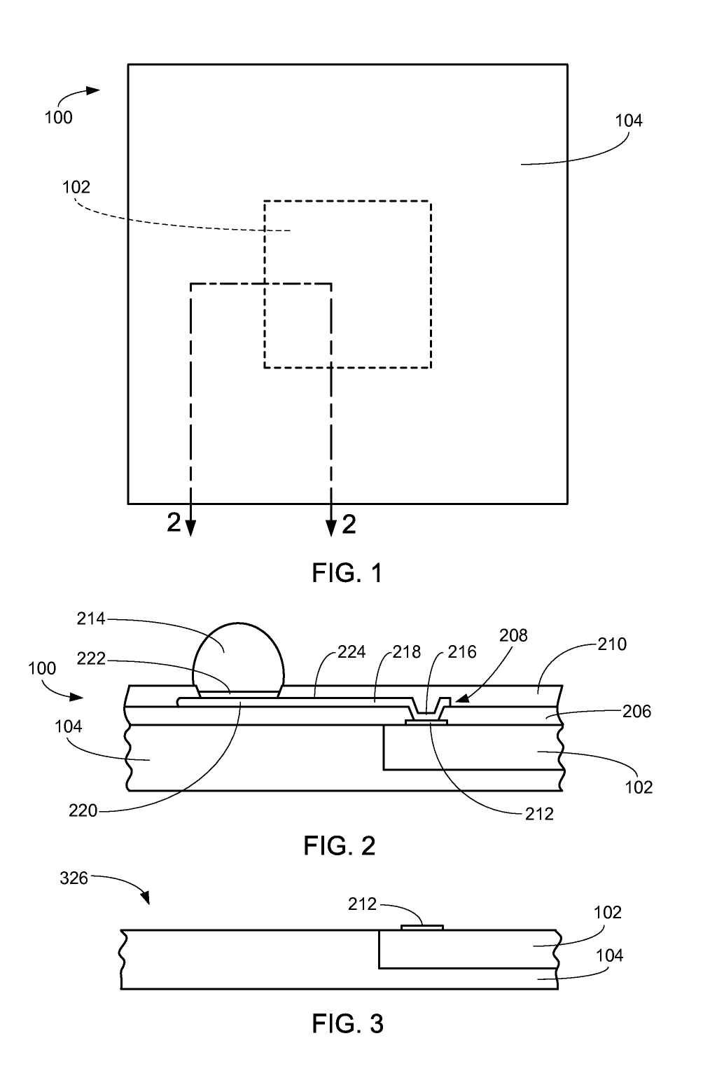

Referring now to FIG. 1, therein is shown a plan view of an integrated circuit packaging system 100 in a first embodiment of the present invention. The plan view shows an integrated circuit die 102 and an encapsulation 104, the integrated circuit die 102 shown with dotted lines to indicate that it is not normally visible from the outside.

The integrated circuit die 102 is covered by the encapsulation 104, which can be made from a material such as epoxy molding compound, curable underfill, or other moldable compound or type of encapsulant, for example.

Referring now to FIG. 2, therein is shown a cross-sectional view of the integrated circuit packaging system 100 along the section line 2-2 of FIG. 1. This view shows the integrated circuit die 102, the encapsulation 104, a lower passivation layer 206, a redistribution layer 208, and an upper passivation layer 210.

The integrated circuit die 102 is embedded in the encapsulation 104. The top surface of the encapsulation 104 can be coplanar with the active side of the integrated circuit die 102, which can have contact pads 212 on the active side. One of the contact pads 212 is shown connected to the redistribution layer 208 and subsequently to one of the external interconnects 214. The external interconnects 214, such as solder balls, can function to electrically connect the integrated circuit die 102 to the outside. The redistribution layer 208 connects to the contact pads 212 through the lower passivation layer 206, which can be formed from a dielectric material which can be photoimagable.

The redistribution layer 208 is a conductive structure for redistributing electrical signals. The redistribution layer 208 connects the integrated circuit die 102 to the external interconnects 214. The redistribution layer 208 has chip contacts 216 on the contact pads 212 connected to traces 218 which connect on the other end of the traces 218 to bump pads 220. The redistribution layer 208 can have many groups of the chip contacts 216, the traces 218, and the bump pads 220 arranged in a “fan-in” or “fan-out” configuration to provide as much or as little connectivity as is required. The chip contacts 216 can be formed through the lower passivation layer 206 while the traces 218 and the bump pads 220 can be positioned on top of the lower passivation layer 206.

The bump pads 220 can be in direct contact with the external interconnects 214 or can connect to the external interconnects 214 through an adhesion layer 222, which can be on the bump pads 220 exposed through holes in the upper passivation layer 210. The adhesion layer 222 can function to enhance the adhesion of solder to the bump pads 220. The upper passivation layer can cover and be in direct contact with the lower passivation layer 206 and the redistribution layer 208. Holes in the upper passivation layer 210 can expose the bump pads 220 of the redistribution layer 208. The adhesion layer 222 can be formed from a material such as copper, nickel, gold, palladium, tin, a combination thereof, or some other conductive material or mixture thereof. The external interconnects 214 can then be in direct contact with the adhesion layer 222. However, it is understood that the external interconnects 214 can instead be connected directly to the bump pads 220 without the adhesion layer 222.

It has been discovered that the adhesion layer 222 on the redistribution layer 208 improves reliability of the integrated circuit packaging system 100. If the redistribution layer 208 is formed using a conductive ink, for example, the solderability of the redistribution layer 208 can be improved by adding the adhesion layer 222 which functions as a solderability enhancer. The enhanced adhesion of the solder to the adhesion layer 222 ensures a stronger bond between the external interconnects 214 and the redistribution layer 208, improving reliability and reducing the chance of cracking or delamination.

The upper passivation layer 210 can be formed from a dielectric which can be photoimagable. The upper passivation layer 210 can be patterned with holes to allow the external interconnects 214 to directly contact the redistribution layer 208 or the adhesion layer 222. The redistribution layer 208 can have a curved top surface 224 (more clearly seen in FIG. 6) as a result of surface tension and being printed or deposited with conductive ink which is cured to harden the redistribution layer 208. The curved top surface 224 can have the highest point central to the curved top surface 224 to take a convex shape, for example.

It has been discovered that the curved top surface 224, whether with the adhesion layer 222 or not, improves the adhesion of the external interconnects 214 to the redistribution layer 208. As compared to a flat surface, the surface area for adhesion to the external interconnects 214 is increased on the curved top surface 224 of the redistribution layer 208, which allows for a better bond between the curved top surface 224 and the external interconnects 214. It is understood that if the adhesion layer 222 is deposited on the redistribution layer 208, the top of the adhesion layer 222 will take on the same curved characteristics of the curved top surface 224 of the redistribution layer 208.

Referring now to FIG. 3, therein is shown a cross-sectional view of a wafer 326 in a manufacturing step of the integrated circuit packaging system 100 of FIG. 2. The wafer 326 is shown as a reconfigured wafer, but it is understood that the process is not limited to reconfigured wafers. For example, the process could be a wafer-level re-distribution layer (RDL) process. A portion of the wafer 326 is shown, which can have an array of the integrated circuit die 102 in the encapsulation 104. Also shown in this view is one of the contact pads 212 of the integrated circuit die 102.

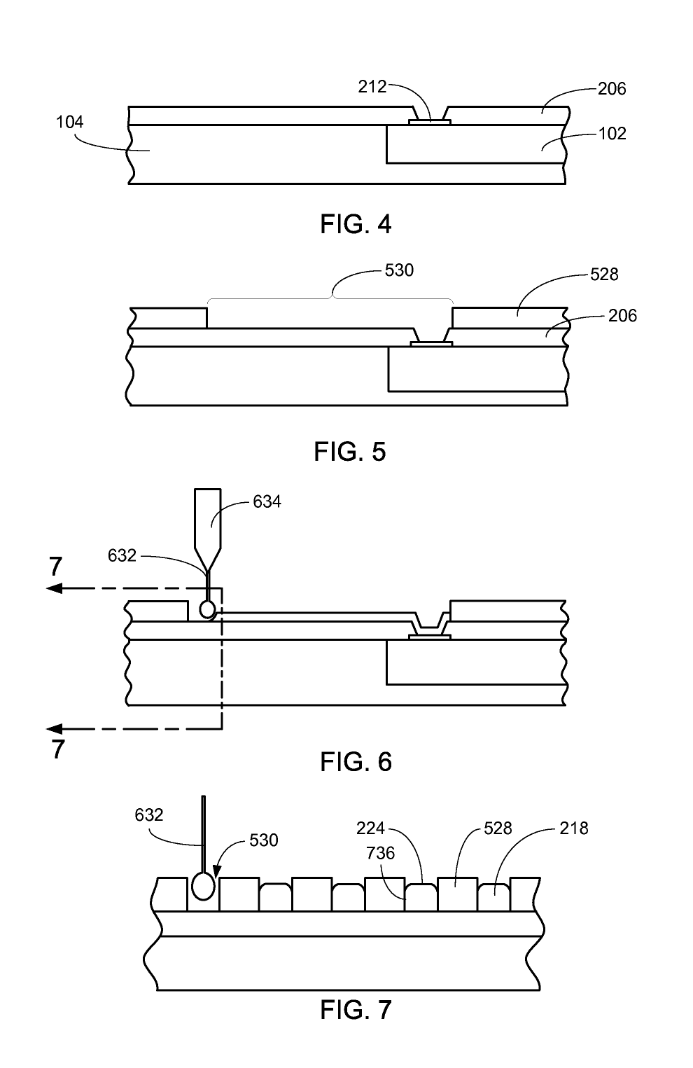

Referring now to FIG. 4, therein is shown the structure of FIG. 3 in a lower passivation phase of manufacture. The lower passivation layer 206 is deposited and patterned on the top of the encapsulation 104 and the active side of the integrated circuit die 102 leaving the contact pads 212 exposed.

Referring now to FIG. 5, therein is shown the structure of FIG. 4 in a pattern mask application phase of manufacture. A pattern mask 528 is deposited on the lower passivation layer 206 with mask openings 530 that correspond to the desired pattern of the redistribution layer 208 of FIG. 2. The pattern mask 528 can be made from a material such as photoresist, for example. The pattern mask 528 can be deposited or formed using a photolithographic process, for example.

Referring now to FIG. 6, therein is shown the structure of FIG. 5 in a printing phase of manufacture. In this phase the redistribution layer 208 of FIG. 2 is formed by printing or jetting conductive ink 632 into the mask openings 530, which define the lateral dimensions of the redistribution layer 208. In this example, the conductive ink 632 is deposited from a nozzle 634. The conductive ink 632 can be a metallic nano-particle ink with the particles suspended in an epoxy, polymer, or phenolic resin base substance, for example. The conductive ink 632 can be cured or sintered through heat or UV light, for example. The printing phase is described as using the conductive ink 632, but it is understood that printing can also be done using a conductive paste which can also be a metallic nano-particle paste suspended in an epoxy, polymer, or phenolic resin base substance curable or sinterable using heat, for example. As another example, the conductive paste can be a low temperature sintering conductive paste which can be sintered at a temperature as low as 200 degrees Celsius, for example.

It has been discovered that printing the conductive ink 632 to form the redistribution layer 208 of the integrated circuit packaging system 100 of FIG. 2 improves process throughput and reduces cost of manufacture. Because the conductive ink 632 can be printed without laying down a seed layer, a subsequent step to remove excess portions of the seed layer is unnecessary, which reduces the number of process steps along with reducing waste.

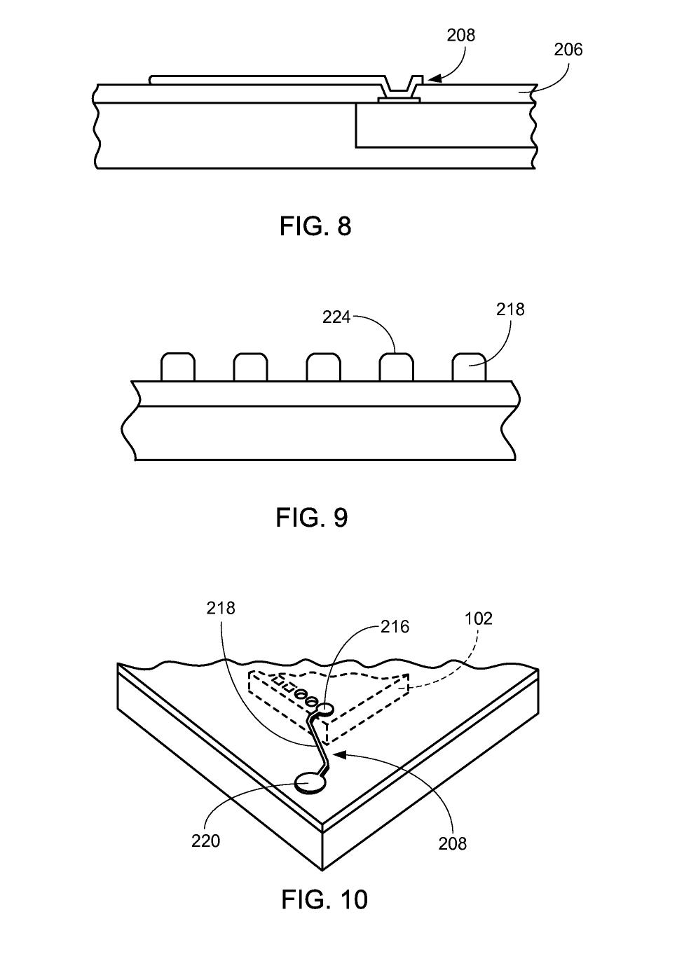

Referring now to FIG. 7, therein is shown a cross-sectional view of the structure of FIG. 6 along the section line 7-7 of FIG. 6. In this view can be clearly seen a cross-section of the traces 218 of the redistribution layer 208 of FIG. 2 along with the curved top surface 224 of the redistribution layer 208. The conductive ink 632 in the process of printing or jetting (similar to an inkjet printer, for example) can be seen on the left side of the figure as the conductive ink 632 is deposited into the mask openings 530 of the pattern mask 528.

The deposition of the conductive ink 632 into the pattern mask 528 creates sidewalls 736 to the redistribution layer 208. The sidewalls 736 are planar due to contact with the planar sides of the mask openings 530. The sidewalls 736 and the curved top surface 224 are characteristics of the redistribution layer 208 being formed with the conductive ink 632, a liquid, and the characteristic shape remains after the conductive ink 632 is cured to harden the conductive ink 632 into the redistribution layer 208. The traces 218 formed from the conductive ink 632 can be formed with a line spacing or pitch of under 30 μm. Described another way, the process for depositing the traces 218 with the conductive ink 632 printed into the pattern mask 528 can have a width/spacing capability of under 30/30 μm—in other words, the traces 218 can be less than 30 μm in width and each of the traces 218 can be separated from other adjacent traces by a gap of less than 30 μm.

It has been discovered that the traces 218 printed into the pattern mask 528 greatly improves the ability to shrink dimensions of the redistribution layer 208 below that of traces formed by printing the conductive ink 632 on an unpatterned surface. Due to the characteristics of ink jet printing, without the use of the pattern mask 528, smearing occurs when attempting to go below a width/spacing capability of 30/30 μm, which renders the printed pattern unusable. The use of the pattern mask 528 in conjunction with the conductive ink 632 gives the benefits of the conductive ink 632 to form the redistribution layer 208 while also allowing the formation of fine structures even below a 10/10 μm width/spacing capability.

Referring now to FIG. 8, therein is shown the structure of FIG. 6 in a pattern mask stripping phase of manufacture. After the deposition of the conductive ink 632 of FIG. 6 to form the redistribution layer 208, the conductive ink 632 can be cured using heat or UV radiation, for example. The pattern mask 528 of FIG. 5 can then be removed, leaving the redistribution layer 208 on the lower passivation layer 206. The pattern mask 528 can be removed using an etchant selective for the material of the pattern mask 528 while leaving the lower passivation layer 206 undamaged, for example.

Referring now to FIG. 9, therein is shown the structure of FIG. 7 in the pattern mask stripping phase of manufacture. In this view, the traces 218 having the curved top surface 224 can be seen with gaps between each of the traces 218. For example, the gaps can be under 30 μm across or even under 10 μm across.

Referring now to FIG. 10, therein is shown an exemplary isometric view of a portion of FIG. 8. In this isometric view, only one portion of the redistribution layer 208 is shown, though it is understood that this is for illustrative and clarity purposes only. Clearly seen is one of the chip contacts 216 of the redistribution layer 208 connected to the integrated circuit die 102. The chip contacts 216 are connected to the bump pads 220 through the traces 218, of which one is shown for example only. In a finished package, it is understood that the redistribution layer 208 would consist of more than one set of the chip contacts 216, the traces 218, and the bump pads 220.

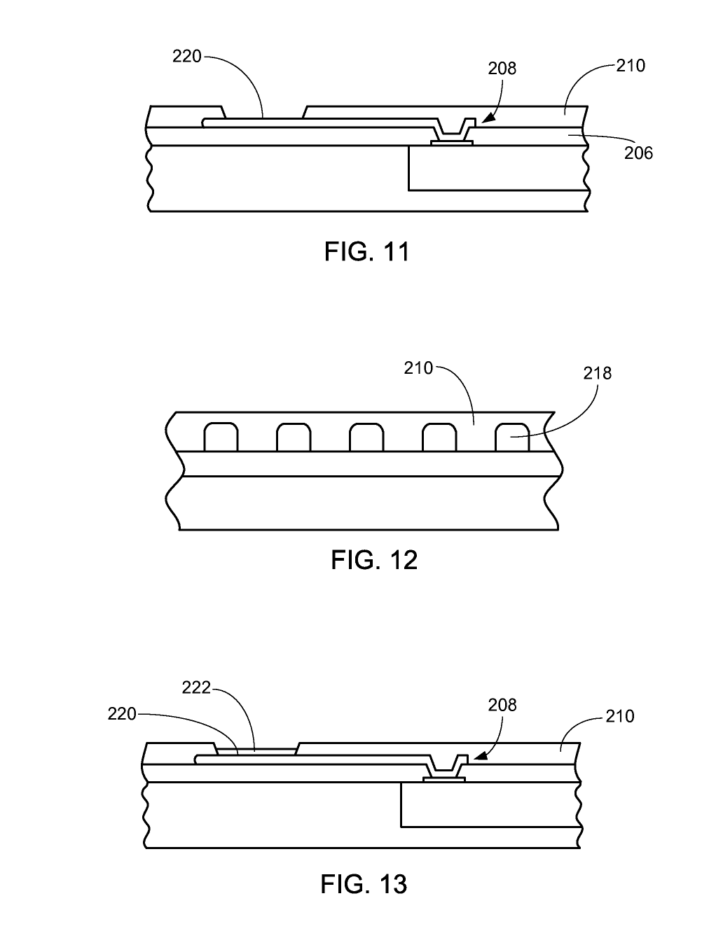

Referring now to FIG. 11, therein is shown the structure of FIG. 8 in an upper passivation phase of manufacture. Following removal of the pattern mask 528 of FIG. 5, the upper passivation layer 210 can be deposited and patterned on the lower passivation layer 206 and the redistribution layer 208, with holes leaving the bump pads 220 of the redistribution layer 208 exposed through the upper passivation layer 210.

Referring now to FIG. 12, therein is shown the structure of FIG. 9 in the upper passivation phase of manufacture. In this view is shown the traces 218 covered by the upper passivation layer 210.

Referring now to FIG. 13, therein is shown the structure of FIG. 11 in a solderability enhancement phase of manufacture. After deposition of the upper passivation layer 210, the adhesion layer 222 can be deposited on the bump pads 220 through a process such as electrolytic or electroless plating or curable conductive ink deposition, for example. The adhesion layer 222 can enhance the connection between a solder ball and the redistribution layer 208. The external interconnects 214 of FIG. 2 can be attached to the bump pads 220 or to the adhesion layer 222 if present to complete the integrated circuit packaging system 100 of FIG. 2.

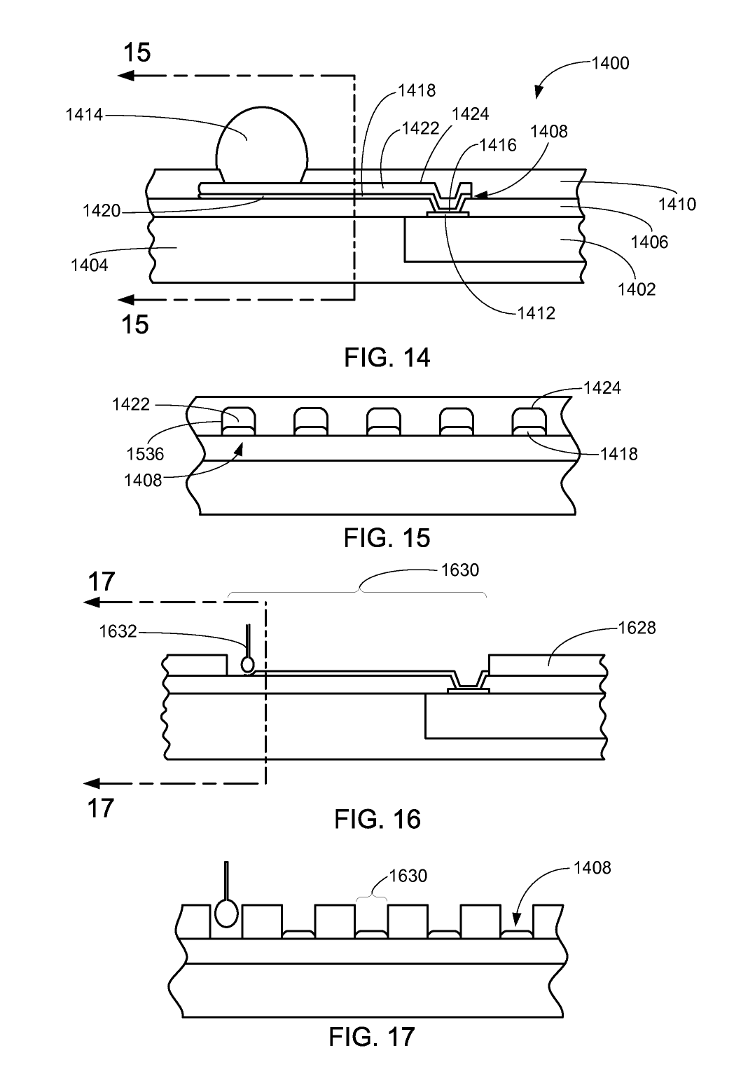

Referring now to FIG. 14, therein is shown a cross-sectional view of the integrated circuit packaging system as exemplified by the top view of FIG. 1 and along the section line 2-2 of FIG. 1 in a second embodiment of the present invention. This view shows an integrated circuit die 1402, an encapsulation 1404, a lower passivation layer 1406, a redistribution layer 1408, and an upper passivation layer 1410.

The integrated circuit die 1402 is embedded in and in direct contact with the encapsulation 1404. The encapsulation 1404 can be made from a material such as epoxy molding compound, curable underfill, or other moldable compound or type of encapsulant, for example. The top surface of the encapsulation 1404 can be coplanar with the active side of the integrated circuit die 1402, which can have contact pads 1412 on the active side. One of the contact pads 1412 is shown connected to the redistribution layer 1408 and subsequently to one of the external interconnects 1414. The external interconnects 1414, such as solder balls, can function to electrically connect the integrated circuit die 1402 to the outside. The redistribution layer 1408 connects to the contact pads 1412 through the lower passivation layer 1406, which can be formed from a dielectric material which can be photoimagable.

The redistribution layer 1408 is a conductive structure for redistributing electrical signals. The redistribution layer 1408 connects the integrated circuit die 1402 to the external interconnects 1414. The redistribution layer 1408 has chip contacts 1416 on the contact pads 1412 connected to traces 1418 which connect on the other end of the traces 1418 to bump pads 1420. The redistribution layer 1408 can have many groups of the chip contacts 1416, the traces 1418, and the bump pads 1420 arranged in a “fan-in” or “fan-out” configuration to provide as much or as little connectivity as is required. The chip contacts 1416 can be formed through the lower passivation layer 1406 while the traces 1418 and the bump pads 1420 can be positioned on top of the lower passivation layer 1406.

The bump pads 1420 can connect to the external interconnects 1414 through an adhesion layer 1422, which can be exposed through holes in the upper passivation layer 1410. The adhesion layer 1422 can be on the entire upper surface of the redistribution layer 1408 and can function to enhance the adhesion of solder to the bump pads 1420. In this example, the redistribution layer 1408 can function as a conductive seed layer made from a material such as conductive ink containing copper or a conductive polymer, or a direct plating conductive agent such as palladium sulfide. The upper passivation layer 1410 can cover and be in direct contact with the lower passivation layer 1406 and the adhesion layer 1422. Holes in the upper passivation layer 1410 can expose the adhesion layer 1422 on the bump pads 1420 of the redistribution layer 1408. The adhesion layer 1422 can be formed from a material such as copper, nickel, gold, palladium, tin, a combination thereof, or some other conductive material or mixture thereof. The external interconnects 1414 can then be in direct contact with the adhesion layer 1422.

It has been discovered that the adhesion layer 1422 on the redistribution layer 1408 improves reliability of the integrated circuit packaging system 1400. If the redistribution layer 1408 is formed using a conductive ink, for example, the solderability of the redistribution layer 1408 can be improved by adding the adhesion layer 1422 which functions as a solderability enhancer. The enhanced adhesion of the solder to the adhesion layer 1422 ensures a stronger bond between the external interconnects 1414 and the redistribution layer 1408, improving reliability and reducing the chance of cracking or delamination.

The upper passivation layer 1410 can be formed from a dielectric which can be photoimagable. The upper passivation layer 1410 can be patterned with holes to allow the external interconnects 1414 to directly contact the adhesion layer 1422. The redistribution layer 1408 can have a curved top surface (more clearly seen in FIG. 15) as a result of surface tension and being printed or deposited with conductive ink which is cured to harden the redistribution layer 1408. The adhesion layer 1422 formed on the redistribution layer 1408 can take on the characteristic shape of the curved top surface of the redistribution layer 1408 and have a curved top surface 1424 of the adhesion layer 1422. The curved top surface 1424 can have the highest point central to the curved top surface 1424 such as having a convex shape, for example.

It has been discovered that the curved top surface 1424 of the adhesion layer 1422 improves the adhesion of the external interconnects 1414 to the adhesion layer 1422. As compared to a flat surface, the surface area for adhesion to the external interconnects 1414 is increased on the curved top surface 1424 of the adhesion layer 1422, which allows for a better bond between the curved top surface 1424 and the external interconnects 1414.

Referring now to FIG. 15, therein is shown a cross-sectional view of the structure of FIG. 14 along the section line 15-15 of FIG. 14. In this view can more clearly be seen the curved top surface 1424 of the adhesion layer 1422, which conforms to the curved shape of the top surface of the redistribution layer 1408. The traces 1418 can be seen in cross-section as well, with sidewalls 1536 of the traces 1418 visible. The sidewalls 1536 are planar. The traces 1418 can have a line spacing or pitch of under 30 μm. Described another way, the process for forming the traces 1418 can have a width/spacing capability of under 30/30 μm—in other words, the traces 1418 can be less than 30 μm in width and each of the traces 1418 can be separated from other adjacent traces by a gap of less than 30 μm.

Referring now to FIG. 16, therein is shown a structure similar to the structure of FIG. 5 in a printing phase of manufacture. The manufacturing process for forming the second embodiment of the integrated circuit packaging system 1400 of FIG. 14 up to the application of a pattern mask 1628 is the same as that to reach the process step of FIG. 5. From here, the method of manufacture diverges.

The redistribution layer 1408 of FIG. 14 is formed by printing or jetting conductive ink 1632 into mask openings 1630 of the pattern mask 1628, which define the lateral dimensions of the redistribution layer 1408. In this example, the conductive ink 1632 is deposited as a conductive seed layer. This means that the redistribution layer 1408 has a height less than half of the depth of the mask openings 1630, for example.

It has been discovered that printing the conductive ink 1632 to form the redistribution layer 1408 as a seed layer of the integrated circuit packaging system 1400 of FIG. 14 improves process throughput and reduces cost of manufacture. Because the conductive ink 1632 can be printed as a seed layer directly into the mask openings 1630, a subsequent step to remove excess portions of the seed layer is unnecessary, which reduces the number of process steps along with reducing waste.

Referring now to FIG. 17, therein is shown a cross-sectional view of the structure of FIG. 16 along the section line 17-17 of FIG. 16. The redistribution layer 1408 can be seen having a curved top surface. The height of the redistribution layer 1408 as a seed layer can also be clearly seen to be less than half the height of the depth of the mask openings 1630.

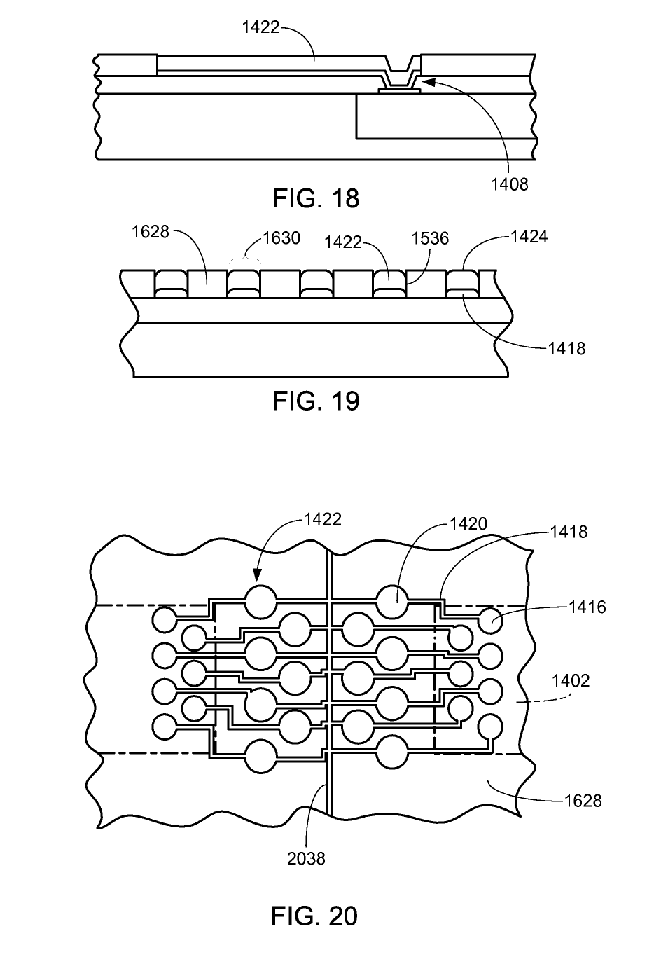

Referring now to FIG. 18, therein is shown the structure of FIG. 16 in a plating phase of manufacture. After the redistribution layer 1408 as a seed layer is deposited, the adhesion layer 1422 can be deposited on the redistribution layer 1408 via a process such as electrolytic or electroless plating.

Referring now to FIG. 19, therein is shown the structure of FIG. 17 in the plating phase of manufacture. In this view can be clearly seen a cross-section of the traces 1418 of the redistribution layer 1408 of FIG. 18 along with the curved top surface 1424 of the adhesion layer 1422. The adhesion layer 1422 can be deposited into the mask openings 1630 of the pattern mask 1628. The adhesion layer 1422 can be of a greater height than the redistribution layer 1408 and the top of the curved top surface 1424 of the adhesion layer 1422 can be the same height as the top of the pattern mask 1628. It is understood that because the adhesion layer 1422 is deposited on the redistribution layer 1408, the top of the adhesion layer 1422 can take on the same curved characteristics of the curvature of the redistribution layer 1408, resulting in the curved top surface 1424 of the adhesion layer 1422.

The deposition of material into the pattern mask 1628 creates the sidewalls 1536 to the redistribution layer 1408 and the adhesion layer 1422. The sidewalls 1536 are planar due to contact with the planar sides of the mask openings 1630. The traces 1418 can be formed with a line spacing or pitch of under 30 μm. Described another way, the process for depositing the traces 1418 with the conductive ink 1632 and material to form the adhesion layer 1422 into the pattern mask 1628 can have a width/spacing capability of under 30/30 μm—in other words, the traces 1418 can be less than 30 μm in width and each of the traces 1418 can be separated from other adjacent traces by a gap of less than 30 μm.

It has been discovered that the traces 1418 printed into the pattern mask 1628 greatly improves the ability to shrink dimensions of the redistribution layer 1408 below that of traces formed by printing the conductive ink 1632 of FIG. 16 on an unpatterned surface. Due to the characteristics of ink jet printing, without the use of the pattern mask 1628, smearing occurs when attempting to go below a width/spacing capability of 30/30 μm, which renders the printed pattern unusable. The use of the pattern mask 1628 in conjunction with the conductive ink 1632 gives the benefits of the conductive ink 1632 to form the redistribution layer 1408 while also allowing the formation of fine structures even below a 10/10 μm width/spacing capability. Plating the adhesion layer 1422 on top of the redistribution layer 1408 while still in the pattern mask 1628 also allows the adhesion layer 1422 to make use of the redistribution layer 1408 as a seed layer while maintaining the desired dimensions as defined by the pattern mask 1628.

Referring now to FIG. 20, therein is shown a top view of a portion of the structure of FIG. 18 in the plating phase of manufacture. In this view is shown the pattern of the redistribution layer 1408 of FIG. 18 entirely covered by the adhesion layer 1422. The pattern of the traces 1418, the chip contacts 1416, and the bump pads 1420 are clearly visible. The integrated circuit die 1402 is shown with dotted lines to indicate being covered by the pattern mask 1628.

Two of the integrated circuit die 1402 are shown to indicate wafer-level manufacture. A bus connector 2038 is visible in the center of the figure which also acts as a saw line. The bus connector 2038 facilitates a continuous plating process to lay down the adhesion layer 1422 across the entire wafer. All of the traces 1418 connect to the bus connector 2038 between individual units which will become the integrated circuit packaging system 1400 of FIG. 14 once the pattern mask 1628 has been removed, the upper passivation layer 1410 of FIG. 14 is deposited, the external interconnects 1414 of FIG. 14 are attached, and the bus connector 2038 is removed by sawing or cutting through the bus connector 2038 and the encapsulation 1404.

The pattern of the redistribution layer 1408 and the adhesion layer 1422 shown is for illustrative purposes only, and it is understood that the redistribution layer 1408 can be patterned differently. For example, while a fan-out pattern is shown on only one side of the integrated circuit die 1402, the fan-out pattern could be on all sides of the integrated circuit die 1402. Also for example, the relative sizes of the integrated circuit die 1402 and the chip contacts 1416 could change such that the chip contacts 1416 are smaller than are shown in the figure.

Because the traces 1418 are all connected to the bus connector 2038 at the edge of what will become the integrated circuit packaging system 1400, this means that the traces 1418 extending out past the bump pads 1420 will extend to the edge of the encapsulation and a cut edge of the traces 1418 will be planar with the edge of the encapsulation 1404 of FIG. 14 due to being separated from the bus connector 2038 through a singulation process such as sawing or cutting. The singulation process will leave a planar edge of the encapsulation 1404 and the cut edge of the traces 1418.

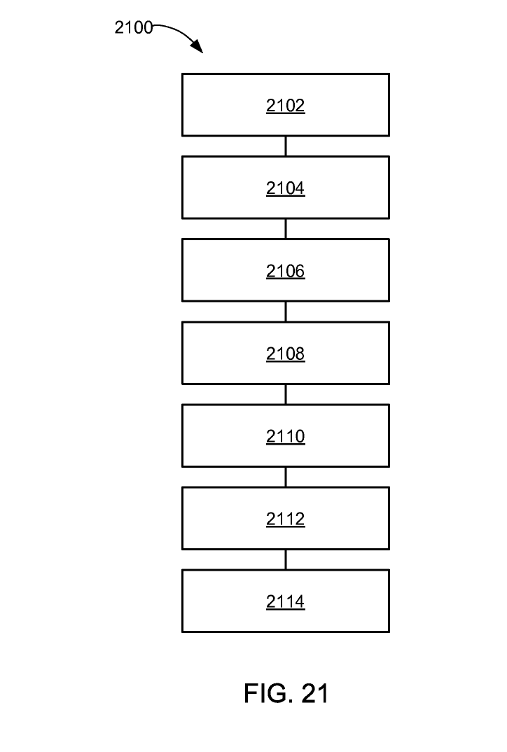

Referring now to FIG. 21, therein is shown a flow chart of a method 2100 of manufacture of the integrated circuit packaging system 100 in a further embodiment of the present invention. The method 2100 includes: providing an integrated circuit die having a contact pad in a block 2102; depositing a lower passivation layer on the integrated circuit die leaving the contact pad exposed in a block 2104; patterning a pattern mask having mask openings on the lower passivation layer in a block 2106; forming a redistribution layer on the contact pad and the lower passivation layer by depositing a conductive ink in the mask openings in a block 2108; removing the pattern mask in a block 2110; depositing an upper passivation layer over the redistribution layer leaving a portion of the redistribution layer exposed in a block 2112; and attaching an external interconnect to the redistribution layer in a block 2114.

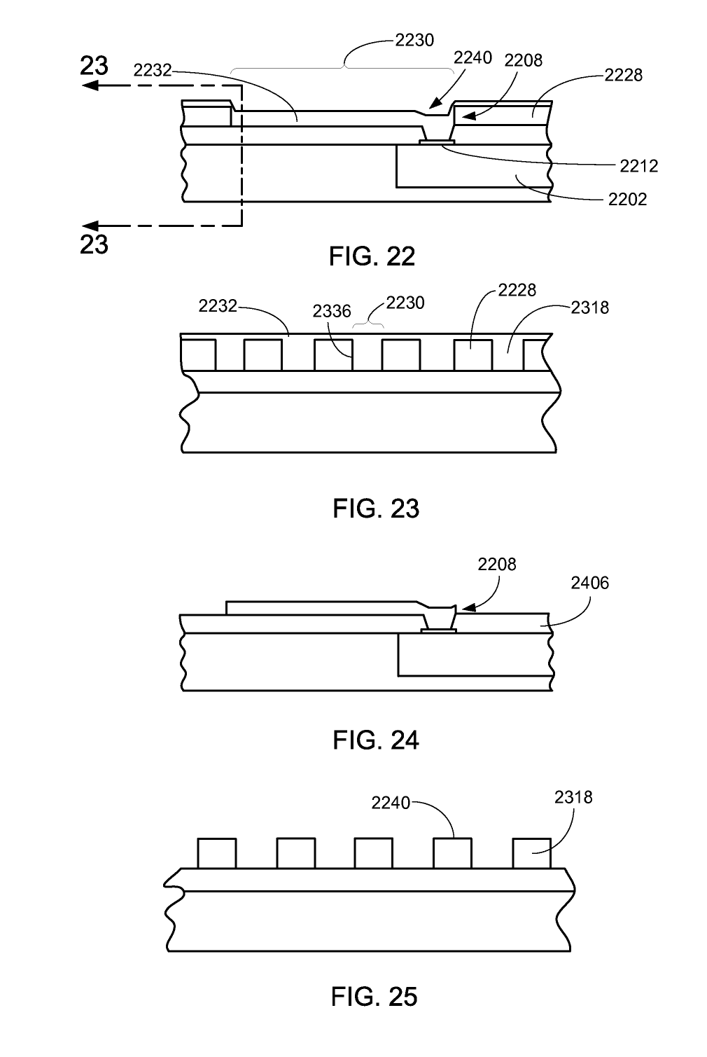

Referring now to FIG. 22, therein is shown a structure similar to the structure of FIG. 5 in an alternative printing phase of manufacture. The manufacturing process for forming an alternative embodiment of the integrated circuit packaging system 100 of FIG. 2 up to the application of a pattern mask 2228 is the same as that to reach the process step of FIG. 5. From here, the method of manufacture diverges.

In this phase a redistribution layer 2208 is formed by depositing conductive ink 2232 into mask openings 2230 of the pattern mask 2228, which define the lateral dimensions of the redistribution layer 2208. In this example, the conductive ink 2232 is deposited by spray coating, slit coating, or simply ink jetting over the entire exposed surface. The conductive ink 2232 fills the mask openings 2230, but a portion of the conductive ink 2232 also ends up on the surface of the pattern mask 2228. Because of the method of application, the surface of the conductive ink 2232 can be seen to be slightly lower over the contact pads 2212 of an integrated circuit die 2202. This creates an uneven top surface 2240 of the redistribution layer 2208. The uneven top surface 2240 can be flat and planar besides the area where the height transitions to the slight lower surface of the conductive ink 2232.

It has been discovered that printing the conductive ink 2232 through spray or slit coating or fully coating the surface of a wafer having mask openings 2230 increases manufacturing efficiency and throughput without sacrificing quality. Because a complicated pattern to match with the mask openings 2230 is unnecessary when doing a full coat of the surface, depositing the conductive ink 2232 will be very quick and efficient while the mask openings 2230 insure that there is no reduction in resolution of the necessary features of the redistribution layer 2208.

It has also been discovered that the uneven top surface 2240 of the redistribution layer 2208 can improve reliability of the completed package. The uneven top surface 2240 of the redistribution layer can increase usable surface area for solder balls or other connectors to adhere to, which can increase bond strength and reliability by reducing connection failures.

The conductive ink 2232 can be a metallic nano-particle ink with the particles suspended in an epoxy, polymer, or phenolic resin base substance, for example. The conductive ink 2232 can be cured or sintered through heat or UV light, for example. The printing phase is described as using the conductive ink 2232, but it is understood that printing can also be done using a conductive paste which can also be a metallic nano-particle paste suspended in an epoxy, polymer, or phenolic resin base substance curable or sinterable using heat, for example. As another example, the conductive paste can be a low temperature sintering conductive paste which can be sintered at a temperature as low as 200 degrees Celsius, for example.

It has been discovered that printing the conductive ink 2232 to form the redistribution layer 2208 improves process throughput and reduces cost of manufacture. Because the conductive ink 2232 can be printed without laying down a seed layer, a subsequent step to remove excess portions of the seed layer is unnecessary, which reduces the number of process steps along with reducing waste.

Referring now to FIG. 23, therein is shown a cross-sectional view of the structure of FIG. 22 along the section line 23-23 of FIG. 22. In this view can be clearly seen a cross-section of traces 2318 of the redistribution layer 2208 of FIG. 22.

The deposition of the conductive ink 2232 into the pattern mask 2228 creates sidewalls 2336 to the redistribution layer 2208. The sidewalls 2336 are planar due to contact with the planar sides of the mask openings 2230. The sidewalls 2336 and the uneven top surface 2240 of FIG. 22 are characteristics of the redistribution layer 2208 being formed with the conductive ink 2232, a liquid, and the characteristic shape remains after the conductive ink 2232 is cured to harden the conductive ink 2232 into the redistribution layer 2208. The traces 2318 formed from the conductive ink 2232 can be formed with a line spacing or pitch of under 30 μm. Described another way, the process for depositing the traces 2318 with the conductive ink 2232 printed into the pattern mask 2228 can have a width/spacing capability of under 30/30 μm—in other words, the traces 2318 can be less than 30 μm in width and each of the traces 2318 can be separated from other adjacent traces by a gap of less than 30 μm.

It has been discovered that the traces 2318 printed into the pattern mask 2228 greatly improves the ability to shrink dimensions of the redistribution layer 2208 below that of traces formed by printing the conductive ink 2232 on an unpatterned surface. Due to the characteristics of ink jet printing, without the use of the pattern mask 2228, smearing occurs when attempting to go below a width/spacing capability of 30/30 μm, which renders the printed pattern unusable. The use of the pattern mask 2228 in conjunction with the conductive ink 2232 gives the benefits of the conductive ink 2232 to form the redistribution layer 2208 while also allowing the formation of fine structures even below a 10/10 μm width/spacing capability.

Referring now to FIG. 24, therein is shown the structure of FIG. 22 in a pattern mask stripping phase of manufacture. After the deposition of the conductive ink 2232 of FIG. 22 to form the redistribution layer 2208, the conductive ink 2232 can be cured using heat or UV radiation, for example. The pattern mask 2228 of FIG. 22 can then be removed, leaving the redistribution layer 2208 on a lower passivation layer 2406. The pattern mask 2228 can be removed using an etchant selective for the material of the pattern mask 2228 while leaving the lower passivation layer 2406 undamaged, for example. The residual portions of the conductive ink 2232 on the surface of the pattern mask 2228 can be removed at the same time as the removal of the pattern mask 2228.

Referring now to FIG. 25, therein is shown the structure of FIG. 23 in the pattern mask stripping phase of manufacture. In this view, the traces 2318 having the uneven top surface 2240 can be seen with gaps between each of the traces 2318. For example, the gaps can be under 30 μm across or even under 10 μm across.

The resulting method, process, apparatus, device, product, and/or system is straightforward, cost-effective, uncomplicated, highly versatile and effective, can be surprisingly and unobviously implemented by adapting known technologies, and are thus readily suited for efficiently and economically manufacturing integrated circuit packaging systems/fully compatible with conventional manufacturing methods or processes and technologies.

Another important aspect of the present invention is that it valuably supports and services the historical trend of reducing costs, simplifying systems, and increasing performance.

These and other valuable aspects of the present invention consequently further the state of the technology to at least the next level.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

What is claimed is:

1. A method of manufacture of an integrated circuit packaging system comprising:
providing an integrated circuit die having a contact pad;
depositing a lower passivation layer on the integrated circuit die leaving the contact pad exposed;
patterning a pattern mask having mask openings on the lower passivation layer;
forming a redistribution layer on the contact pad and the lower passivation layer by depositing a conductive ink in the mask openings;
removing the pattern mask;
depositing an upper passivation layer over the redistribution layer leaving a portion of the redistribution layer exposed; and
attaching an external interconnect to the redistribution layer.

2. The method as claimed in claim 1 further comprising depositing an adhesion layer on the redistribution layer.

3. The method as claimed in claim 1 wherein forming the redistribution layer includes forming the redistribution layer having a chip contact, a trace, and a bump pad.

4. The method as claimed in claim 1 further comprising providing an encapsulation on the integrated circuit die.

5. The method as claimed in claim 1 wherein patterning the pattern mask includes using photolithography to pattern a photoresist.

6. A method of manufacture of an integrated circuit packaging system comprising:
providing an integrated circuit die having a contact pad;
providing an encapsulation on the integrated circuit die leaving the contact pad exposed;
depositing a lower passivation layer on the integrated circuit die leaving the contact pad exposed;
patterning a pattern mask having mask openings on the lower passivation layer;
forming a redistribution layer on the contact pad and the lower passivation layer by depositing a conductive ink in the mask openings, the redistribution layer having a chip contact, a trace, and a bump pad;
depositing an adhesion layer on the redistribution layer;
removing the pattern mask;
depositing an upper passivation layer over the redistribution layer leaving the area above the bump pad of the redistribution layer exposed; and
attaching an external interconnect to the adhesion layer over the bump pad.

7. The method as claimed in claim 6 wherein depositing the adhesion layer includes depositing the adhesion layer only on the bump pad of the redistribution layer.

8. The method as claimed in claim 6 wherein depositing an adhesion layer includes depositing the adhesion layer across the entire surface of a redistribution layer.

9. The method as claimed in claim 6 wherein depositing the adhesion layer includes depositing the adhesion layer only on the bump pad of the redistribution layer through the upper passivation layer.

10. The method as claimed in claim 6 wherein depositing the conductive ink includes printing, jetting, or spraying the conductive ink.

11. An integrated circuit packaging system comprising:
an integrated circuit die having a contact pad;
a redistribution layer on the contact pad, the redistribution layer having a chip contact, a trace, and a bump pad, the redistribution layer having a curved top surface and sidewalls which are planar;
an upper passivation layer on the sidewalls of the redistribution layer with the area above the bump pad of the redistribution layer exposed from the upper passivation layer; and
an external interconnect attached over the bump pad.

12. The system as claimed in claim 11 further comprising an adhesion layer on the redistribution layer.

13. The system as claimed in claim 11 further comprising an encapsulation on the integrated circuit die.

14. The system as claimed in claim 11 further comprising a lower passivation layer between and on the integrated circuit die and the redistribution layer.

15. The system as claimed in claim 11 wherein the upper passivation layer is over the redistribution layer.

16. The system as claimed in claim 11 further comprising:
an encapsulation on the integrated circuit die;
a lower passivation layer between and on the integrated circuit die and the redistribution layer, the lower passivation layer on the encapsulation; and
an adhesion layer having a curved top surface on the redistribution layer.

17. The system as claimed in claim 16 wherein the adhesion layer is only on the bump pad of the redistribution layer.

18. The system as claimed in claim 16 wherein an adhesion layer covers the entire surface of a redistribution layer.

19. The system as claimed in claim 16 wherein the external interconnect is directly on the curved top surface of the adhesion layer.

20. The system as claimed in claim 16 wherein the redistribution layer is formed from conductive ink which has been cured.
